(19) United States
(12) Patent Application Publication
(10) Pub. No.: US 2016/0236381 A1
(43) Pub. Date: Aug. 18, 2016

(54) IMPRINT APPARATUS AND METHOD OF MANUFACTURING ARTICLE

(71) Applicant: CANON KABUSHIKI KAISHA, Tokyo (JP)

(72) Inventor: Shun Takemura, Utsunomiya-shi (JP)

(21) Appl. No.: 15/007,729

(22) Filed: Jan. 27, 2016

(30) Foreign Application Priority Data
Feb. 13, 2015 (JP) 2015-026967

(51) Int. Cl. B29C 43/58; B29C 59/02; G03F 7/00

(52) U.S. Cl. CPC B29C 43/58; G03F 7/0002; B29C 59/022; B29C 59/026; B29C 2043/585; B29L 2031/3406

(57) ABSTRACT

The present invention provides an imprint apparatus which performs an imprint process of forming a pattern on an imprint material on a substrate by using a mold, the apparatus including a detection unit configured to detect an occurrence of an error while the imprint process is performed, and a control unit configured to perform error processing of ceasing the imprint process and unloading the substrate from the imprint apparatus upon curing the imprint material on the substrate when the detection unit detects the occurrence of the error before the imprint material on the substrate is cured.

### BACKGROUND OF THE INVENTION

1. Field of the Invention

The present invention relates to an imprint apparatus and a method of manufacturing an article.

2. Description of the Related Art

With an increasing demand for the miniaturization of semiconductor devices, attention has been paid to an imprint apparatus which forms a pattern on an imprint material (resin) on a substrate by using a mold in addition to a conventional photolithography technique. The imprint apparatus can form a fine pattern (structure) on the order of several nm on a substrate.

As one method of curing an imprint material in an imprint apparatus, there is available a photo-curing method of curing an imprint material by irradiation with light such as ultraviolet light. An imprint apparatus using the photo-curing method cures an imprint material on a short region (imprint region) on a substrate by irradiating the imprint material with light while the imprint material is in contact with a mold, and releases the mold from the cured imprint material, thereby forming a pattern.

In addition, the imprint apparatus sometimes suffers from errors caused by various factors, which disable the continuation (succession) of an imprint process while performing the imprint process of forming a pattern on a substrate. Japanese Patent Laid-Open No. 2011-49405 discloses a technique of performing control in a semiconductor exposure apparatus to have information of restoration methods concerning errors that occur in the main body unit and information of a plurality of types of evaluation values corresponding to the restoration methods and restore the main body unit based on a priority order.

As described above, the imprint apparatus supplies (applies) an imprint material onto a substrate (shot region) and cures the imprint material by irradiation with light while the imprint material is in contact with a mold. In some cases, therefore, an error that disables the continuation of an imprint process occurs in the imprint apparatus, and a substrate is unloaded from the apparatus while the imprint material is not cured. Chemicals emitted from the uncured imprint material contaminate an apparatus which conveys the substrate, an external apparatus into which the substrate unloaded from the imprint apparatus is loaded, and the like. The technique disclosed in Japanese Patent Laid-Open No. 2011-49405 is advantageous in restoring a semiconductor exposure apparatus but does not solve the above problem unique to the imprint apparatus.

### SUMMARY OF THE INVENTION

The present invention provides an imprint apparatus advantageous in reducing contamination caused by an uncured imprint material on a substrate.

According to one aspect of the present invention, there is provided an imprint apparatus which performs an imprint process of forming a pattern on an imprint material on a substrate by using a mold, the apparatus including a detection unit configured to detect an occurrence of an error while the imprint process is performed, and a control unit configured to perform error processing of ceasing the imprint process and unloading the substrate from the imprint apparatus upon curing the imprint material on the substrate when the detection unit detects the occurrence of the error before the imprint material on the substrate is cured.

Further aspects of the present invention will become apparent from the following description of exemplary embodiments with reference to the attached drawings.

### BRIEF DESCRIPTION OF THE DRAWINGS

FIG. 1 is a schematic view showing the arrangement of an imprint apparatus according to one aspect of the present invention.

FIG. 2 is a flowchart for explaining an imprint process and error processing in the imprint apparatus shown in FIG. 1.

FIG. 3 is a flowchart showing the details of error processing shown in FIG. 2.

FIG. 4 is a flowchart showing the details of error processing shown in FIG. 2.

FIG. 5 is a flowchart showing the details of error processing shown in FIG. 2.

### DESCRIPTION OF THE EMBODIMENTS

Preferred embodiments of the present invention will be described below with reference to the accompanying drawings. Note that the same reference numerals denote the same members throughout the drawings, and a repetitive description thereof will not be given.

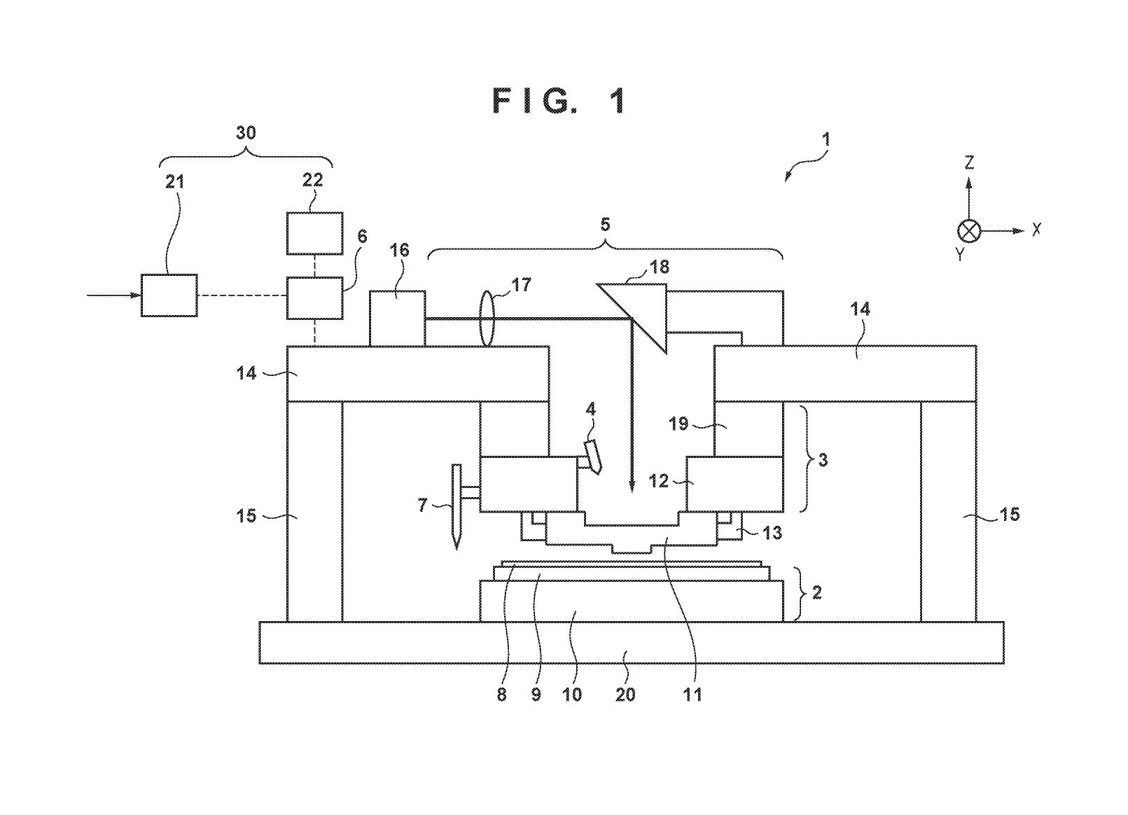

FIG. 1 is a schematic view showing the arrangement of an imprint apparatus 1 according to one aspect of the present invention. The imprint apparatus 1 is a lithography apparatus used for the manufacture of devices such as semiconductor devices as articles. The imprint apparatus 1 performs an imprint process of forming a pattern on an imprint material on a substrate by using a mold. The imprint apparatus 1 transfers the pattern formed on the mold onto the substrate by curing the imprint material, while the imprint material on the substrate is in contact with the mold, and releasing the cured imprint material from the mold. This embodiment uses a resin as an imprint material and adopts, as a resin curing method, a photo-curing method of curing a resin by irradiation with ultraviolet light. In the following description, a direction parallel to the optical axis of an irradiation system which irradiates a resin on a substrate with ultraviolet light (a direction in which a pattern on a mold is brought into contact with an imprint material on a substrate) is defined as the Z-axis, and two directions orthogonal to each other within a plane perpendicular to the Z-axis are respectively defined as the X-axis and the Y-axis.

The imprint apparatus 1 is housed in a clean chamber (not shown) for maintaining an atmosphere in a clean environment. As shown in FIG. 1, the imprint apparatus 1 includes a substrate holding unit 2, a mold holding unit 3, an alignment measuring system 4, an irradiation unit 5, a control unit 6, a resin supply unit 7, a gas supply unit (not shown), and a detection unit 30. The imprint apparatus 1 also includes a bridge plate 14 for holding the mold holding unit 3, columnar supports 15 for supporting the bridge plate 14, and a base plate 20 for holding the substrate holding unit 2.

The substrate holding unit 2 is a unit for holding a substrate 8 and performing alignment (translation shift correction) between the substrate 8 and a mold 11. The substrate holding unit 2 includes a substrate chuck 9 and a substrate stage 10. The substrate chuck 9 holds the substrate 8 with a vacuum suction force or electrostatic force. The substrate chuck 9 is supported on the substrate stage 10 by vacuum suction pads. The substrate stage 10 includes a plurality of driving systems such as a coarse motion driving system and a fine motion driving system, and moves the substrate 8 held on the substrate chuck 9 in the X-axis direction and the Y-axis direction. The substrate stage 10 may also have a function of adjusting the position of the substrate 8 in the Z-axis direction, a function of adjusting the position of the substrate 8 in the θ (rotation around the Z-axis) direction, and a function of adjusting the tilt of the substrate 8.

The substrate 8 includes, for example, a single-crystal silicon substrate, an SOI (Silicon on Insulator) substrate, and a glass substrate. A resin to be molded by the mold 11 is supplied (applied) to the substrate 8.

The mold 11 has a rectangular outer shape, and includes a pattern (a concave-convex pattern to be transferred onto the substrate 8, such as a circuit pattern) three-dimensionally formed on a surface facing the substrate 8. The mold 11 is formed from a material which transmits ultraviolet light, for example, quartz.

The mold holding unit 3 is a unit for holding the mold 11 and bringing a resin on a substrate into contact with the mold 11. The mold holding unit 3 includes a mold chuck 12, a shape adjusting unit 13, and a mold stage 19. The mold chuck 12 holds the mold 11 with a vacuum suction force or electrostatic force. The mold chuck 12 is supported on the mold stage 19 by vacuum suction pads. The mold stage 19 includes a plurality of driving systems such as a coarse motion driving system and a fine motion driving system, and moves the mold 11 held on the mold chuck 12 in the Z-axis direction. In order to bring the resin on the substrate into contact with the pattern on the mold 11, control is performed to reduce the spacing between the mold 11 and the substrate 8. Alternatively, the mold holding unit 3 and the substrate holding unit 2 may be moved relatively or sequentially. In addition, at least one of the mold holding unit 3 and the substrate holding unit 2 may be moved. The mold stage 19 may also have a function of adjusting the positions of the mold 11 in the X-axis direction, the Y-axis direction, and the θ (rotation around the Z-axis) direction, a function of adjusting the tilt of the mold 11, and the like. The shape adjusting unit 13 is arranged on the mold chuck 12 and adjusts (corrects), for example, the shape of the mold 11 (its pattern) by applying a force (displacement) to a side surface of the mold 11 held by the mold chuck 12.

The alignment measuring system 4 detects an alignment mark formed on the substrate 8 and an alignment mark formed on the mold 11, and measures the positional shifts between the substrate 8 and the mold 11 in the X-axis direction and the Y-axis direction and the shape difference (for example, a magnification) between the substrate 8 and the mold 11.

The irradiation unit 5 irradiates the resin on the substrate with ultraviolet light (that is, light for curing the resin on the substrate). The irradiation unit 5 includes a light source 16, an optical system 17 for adjusting ultraviolet light from the light source 16 into suitable light, and a mirror 18 which reflects ultraviolet light from the light source 16 toward the resin on the substrate.

The resin supply unit 7 supplies (applies) a resin onto the substrate 8. According to this embodiment, the resin supply unit 7 includes a resin discharge nozzle (not shown), and discharges a resin from the resin discharge nozzle to the substrate 8. The supply amount of resin supplied from the resin supply unit 7 is set in accordance with, for example, the thickness (residual film thickness) or density of the pattern on the resin formed on the substrate 8.

The gas supply unit supplies a gas to a space between the resin on the substrate and the mold 11 through a gas supply nozzle arranged near the mold 11. In other words, the gas supply unit replaces the atmosphere in the space between the resin on the substrate and the mold 11 with a desired gas. Such a gas includes helium gas having high diffusivity.

The detection unit 30 detects an error while an imprint process is performed. Such an error is, for example, an error that disables the continuation (succession) of the imprint process and, in particular, an error that makes it necessary to immediately unload the substrate 8 having undergone the imprint process from the imprint apparatus 1. In addition, such an error is caused by an abnormality inside and outside the imprint apparatus 1.

The detection unit 30 includes a first detection unit 22 which detects the occurrence of an error by detecting a change in the internal environment of the imprint apparatus 1 and a second detection unit 21 which detects the occurrence of an error by detecting a change in the external environment of the imprint apparatus 1. In addition, in this embodiment, the detection unit 30 may detect both a change in the internal environment of the imprint apparatus 1 and a change in the external environment of the imprint apparatus 1. However, the detection unit 30 may detect at least one of a change in the internal environment of the imprint apparatus 1 and a change in the external environment of the imprint apparatus 1.

The first detection unit 22 includes, for example, a temperature sensor, a pressure sensor, a flow rate sensor, a displacement sensor, and a light amount sensor, and detects at least one of a temperature, a pressure, and the constituent concentration of a gas in a space where an imprint process is performed. The second detection unit 21 includes, for example, a reception unit which receives an abnormal signal from the outside of the imprint apparatus 1, and detects vibration transferred to the imprint apparatus 1. As an abnormal signal from the outside, it is possible to use a signal for the transition of the imprint apparatus 1 to a safe state by using information such as an earthquake early warning before the transfer of vibration (quake) from an earthquake's epicenter. In addition, as an external abnormal signal received by the second detection unit 21, it is possible to use a signal informing a power failure or fire. Note that these external abnormal signals may be input to the control unit 6 not via the second detection unit 21.

The control unit 6 includes a CPU and a memory, and controls the overall operation of the imprint apparatus 1. The control unit 6 performs an imprint process by controlling the operation, adjustment, and the like of each unit of the imprint apparatus 1. In addition, when the detection unit 30 detects the occurrence of an error before a resin on a substrate is cured, the control unit 6 ceases an imprint process, and performs error processing of unloading the substrate 8 from the imprint apparatus 1 upon curing the resin on the substrate.

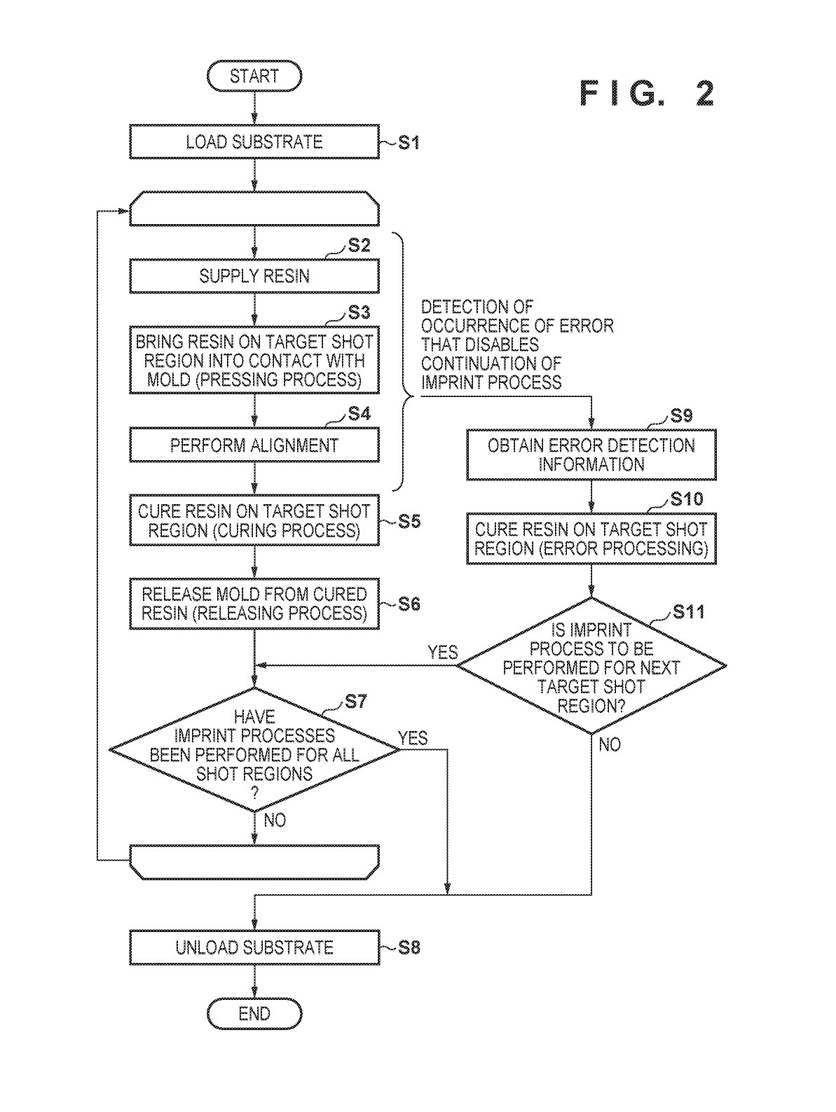

An imprint process and error processing in the imprint apparatus 1 will be described with reference to FIG. 2. As described above, the control unit 6 performs an imprint process and error processing by comprehensively controlling the respective units of the imprint apparatus 1.

In step S1, the control unit 6 causes a substrate conveying mechanism (not shown) to load the substrate 8 into the imprint apparatus 1, and causes the substrate holding unit 2 to hold the substrate 8. In step S2, the control unit 6 causes the resin supply unit 7 to supply a resin to a target shot region (a shot region for which an imprint process is to be performed) on the substrate 8.

In step S3, the control unit 6 brings the target shot region on the substrate 8 into contact with the mold 11 (pressing process). In step S4, the control unit 6 aligns the substrate 8 with the mold 11 so as to match an alignment mark formed on the substrate 8 with an alignment mark formed on the mold 11 based on a measurement result obtained by the alignment measuring system 4. Note however that if a global alignment scheme is adopted as an alignment scheme for the substrate 8 and the mold 11, it is possible to omit alignment (step S4) between the substrate 8 and the mold 11. In addition, although alignment is performed after a pressing process in this embodiment, alignment may be performed before a pressing process in step S3 after the supply of a resin onto the substrate in step S2 based on a measurement result obtained by the alignment measuring system 4. Furthermore, alignment may be performed during a pressing process in step S3.

In step S5, the control unit 6 causes the irradiation unit 5 to cure the resin on the target shot region on the substrate 8 by irradiating the resin with ultraviolet light through the mold 11 upon filling the pattern on the mold 11 with the resin (curing process). In step S6, the control unit 6 releases the mold 11 from the cured resin on the target shot region on the substrate 8 (releasing process). With this processing, a resin pattern corresponding to the pattern on the mold 11 is formed on the target shot region on the substrate 8.

In step S7, the control unit 6 determines whether imprint processes have been performed for all the shot regions on the substrate 8. If imprint processes have not been performed for all the shot regions on the substrate 8, the process shifts to step S2 to set a shot region for which no imprint process has been performed as a target shot region. Note that if a resin has been supplied onto a plurality of shot regions on the substrate 8, it is possible to omit the step of supplying the resin in step S2. Repeating the processing from step S2 to step S7 forms resin patterns on all the shot regions on the substrate 8. In contrast to this, if imprint processes have been performed for all the shot regions on the substrate 8, the process shifts to step S8. In step S8, the control unit 6 causes the substrate conveying mechanism to unload the substrate 8 having undergone imprint processes on all the shot regions from the imprint apparatus 1.

Assume that in this case, the detection unit 30 has detected the occurrence of an error, that is, an error that disables the continuation of an imprint process, before the resin on the substrate is cured, more specifically, during the interval (from step S2 to the start of step S5) from the instant the resin is supplied onto the substrate to the instant the resin is cured. In this case, the control unit 6 ceases the imprint process and performs error processing, as described above.

More specifically, in step S9, the control unit 6 obtains error detection information from the detection unit 30. The error detection information includes not only information indicating the detection of the occurrence of an error but also information indicating the state of an imprint process at the time of the occurrence of the error, for example, information indicating whether the error has occurred before or after the contact between the resin on the substrate and the mold 11.

In step S10, the control unit 6 causes the irradiation unit 5 to cure the resin on the target short region on the substrate 8 by irradiating the resin with ultraviolet light based on the error detection information obtained in step S9 (error processing). In this case, as will be described later, the control unit 6 cures the resin on the target shot region on the substrate 8 in accordance with the state of an imprint process at the time of the occurrence of the error (that is, performs error processing in accordance with the state of the imprint process).

In step S11, the control unit 6 determines whether to perform an imprint process for the next target shot region on the substrate 8. If an imprint process is to be performed for the next target shot region on the substrate 8, the process shifts to step S7. If an imprint process is not to be performed for the next target shot region on the substrate 8, the process shifts to step S8.

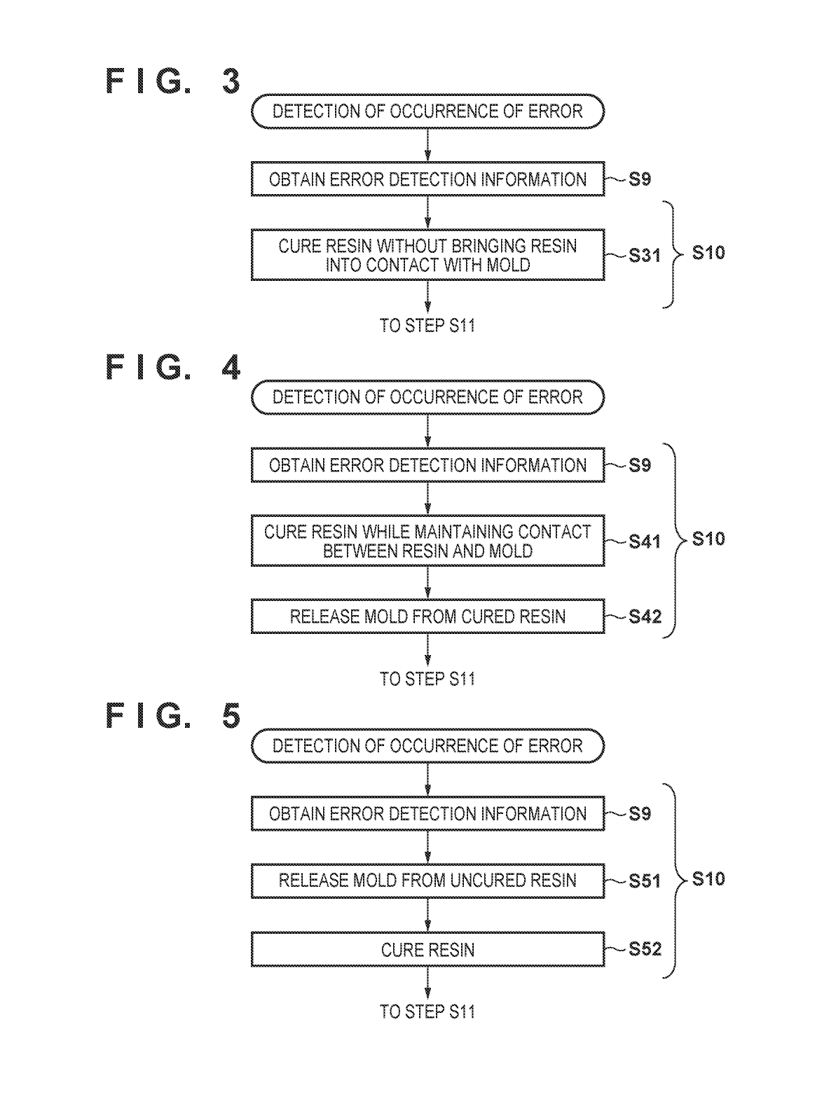

The details of error processing (step S10) will be described below. FIG. 3 is a flowchart showing the details of error processing in a case in which the detection unit 30 has detected the occurrence of an error before a resin supplied onto a substrate is brought into contact with the mold 11. If the detection unit 30 has detected the occurrence of an error before the resin supplied onto the substrate is brought into contact with the mold 11 (that is, during the interval from step S2 to the start of step S3), the control unit 6 performs step S31 as error processing. An error which occurs in this case includes an abnormality in the resin supply unit 7, an abnormality in the substrate holding unit 2, an abnormality in the mold holding unit 3, and an external abnormal signal. Such an abnormality can be detected as an error by at least one of the first detection unit 22 and the second detection unit 21.

In step S31, the control unit 6 causes the irradiation unit 5 to cure the resin by irradiating it with ultraviolet light without bringing the resin on the target shot region on the substrate 8 into contact with the mold 11. In this case, the illuminance of ultraviolet light in the error processing (step S31) may differ from that of ultraviolet light in the curing process (step S5).

As described above, when the occurrence of an error is detected before a resin supplied onto a substrate is brought into contact with the mold 11, the resin is cured without bringing the resin on the substrate into contact with the mold 11, and the substrate 8 with the resin on it being cured is unloaded from the imprint apparatus 1. This can reduce (prevent) contamination by chemicals from the uncured resin on the substrate.

FIG. 4 is a flowchart showing the details of error processing in a case in which the detection unit 30 has detected the occurrence of an error after a resin supplied onto a substrate is brought into contact with the mold 11. When the detection unit 30 has detected the occurrence of an error after the resin supplied onto the substrate is brought into contact with the mold 11 (that is, during the interval from step S3 to the start of step S5), steps S41 and S42 are performed as error processing. An error which occurs in this case includes an abnormality in the substrate holding unit 2, an abnormality in the mold holding unit 3, an abnormality in the alignment measuring system 4, and an external abnormal signal. Such an abnormality can be detected as an error by at least one of the first detection unit 22 and the second detection unit 21.

In step S41, the control unit 6 causes the irradiation unit 5 to cure the resin by irradiating it with ultraviolet light while maintaining the contact between the resin on the target shot region on the substrate 8 and the mold 11 (that is, before the mold 11 is released from the resin on the substrate). In this case, the illuminance of ultraviolet light in the error processing (step S41) may differ from that of ultraviolet light in the curing process (step S5). In step S42, the mold 11 is released from the cured resin on the target shot region on the substrate 8.

As described above, if the occurrence of an error is detected before the resin on the substrate is brought into contact with the mold 11 and cured, the resin is cured while the contact between the resin and the mold 11 is maintained, and the substrate 8 is unloaded from the imprint apparatus 1 while the resin on the substrate is cured. This can reduce (prevent) contamination by chemicals from an uncured resin on a substrate.

FIG. 5 is a flowchart showing the details of another example of error processing in a case in which a resin is supplied onto a substrate, and the detection unit 30 has detected the occurrence of an error after the resin is brought into contact with the mold 11. If the detection unit 30 has detected the occurrence of an error after the resin supplied onto the substrate is brought into contact with the mold 11 (during the interval from step S3 to the start of step S5), steps S51 and S52 are performed as error processing. An error which occurs in this case includes an abnormality in the substrate holding unit 2, an abnormality in the mold holding unit 3, an abnormality in the alignment measuring system 4, and an external abnormal signal. Such an abnormality can be detected as an error by at least one of the first detection unit 22 and the second detection unit 21.

In step S51, the mold 11 is released from the uncured resin on the target shot region on the substrate 8. In step S52, the control unit 6 causes the irradiation unit 5 to cure the resin by irradiating it with ultraviolet light while the mold 11 is released from the uncured resin on the target shot region on the substrate 8. In this case, the illuminance of ultraviolet light in the error processing (step S52) may differ from that of ultraviolet light in the curing process (step S5).

As described above, if the occurrence of an error is detected before the resin on the substrate is brought into contact with the mold 11 and cured, the resin is cured after the mold 11 is released from the uncured resin on the substrate, and the substrate 8 is unloaded from the imprint apparatus 1 while the resin on the substrate is cured. This can reduce (prevent) contamination on apparatuses (the conveying mechanism and the external apparatus) by chemicals from an uncured resin on a substrate.

According to this embodiment, if an error that disables the continuation of an imprint process has occurred, error processing is performed so as to cure an uncured resin on the substrate 8 before the substrate 8 is unloaded from the imprint apparatus 1. The embodiment has exemplified the case in which an imprint process is repeated by supplying a resin to one short region. However, patterns may be formed on a substrate by repeating a pressing process and a curing process after supplying a resin to a plurality of shot regions in advance. In this case, error processing is performed so as to cure not only the resin on a shot region as an imprint process target but also the entire uncured resin (imprint material) supplied in advance. Therefore, the imprint apparatus 1 does not unload the substrate 8 with an uncured resin. This can prevent chemicals emitted from an uncured resin from contaminating apparatuses such as an apparatus which conveys the substrate 8 and an apparatus into which the substrate 8 is loaded.

In addition, in this embodiment, every time the occurrence of an error is detected, a resin on a target shot region on the substrate 8 is cured. Note however that error detection information may be stored in advance, and error processing may be collectively performed after a predetermined number of times of imprint processes are completed (that is, the resin on a plurality of shot regions in each of which the occurrence of an error has been detected may be collectively cured).

A method of manufacturing a device (a semiconductor device, magnetic storage medium, liquid crystal display device, or the like) as an article will be described. This manufacturing method includes a process of forming a pattern on a substrate (a wafer, glass plate, film-like substrate, or the like) by using the imprint apparatus 1. The manufacturing method further includes a process of processing the substrate on which the pattern is formed. The steps in this process can include a step of removing a residual film of the pattern. In addition, the steps can include other known steps such as a step of etching a substrate by using the pattern as a mask. The method of manufacturing an article according to the embodiment is more advantageous than the related art in terms of at least one of the performance and quality of an article, productivity, and a production cost.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2015-026967 filed on Feb. 13, 2015, which is hereby incorporated by reference herein in its entirety.

What is claimed is:

1. An imprint apparatus which performs an imprint process of forming a pattern on an imprint material on a substrate by using a mold, the apparatus comprising:
a detection unit configured to detect an occurrence of an error while the imprint process is performed; and
a control unit configured to perform error processing of ceasing the imprint process and unloading the substrate from the imprint apparatus upon curing the imprint material on the substrate when the detection unit detects the occurrence of the error before the imprint material on the substrate is cured.

2. The apparatus according to claim 1, wherein when an imprint material is supplied onto the substrate and the detection unit detects the occurrence of the error before the imprint material is brought into contact with the mold, the control unit cures the imprint material without bringing the imprint material on the substrate into contact with the mold.

3. The apparatus according to claim 1, wherein when an imprint material is supplied onto the substrate and the detection unit has detected the occurrence of the error after the imprint material is brought into contact with the mold, the control unit cures the imprint material while maintaining contact between the imprint material on the substrate and the mold.

4. The apparatus according to claim 1, wherein when an imprint material is supplied onto the substrate and the detection unit has detected the occurrence of the error after the imprint material is brought into contact with the mold, the control unit cures the imprint material after releasing the mold from the imprint material on the substrate.

5. The apparatus according to claim 1, wherein when an imprint material is supplied onto a plurality of shot regions on the substrate, the control unit cures the imprint material on a shot region different from a shot region for which the imprint process has been performed upon curing of the imprint material on the shot region for which the imprint process has been performed when the detection unit has detected the occurrence of the error.

6. The apparatus according to claim 1, wherein the detection unit detects the occurrence of the error by detecting at least one of a change in an internal environment of the imprint apparatus and a change in an external environment of the imprint apparatus.

7. The apparatus according to claim 6, wherein the internal environment includes at least one of a temperature, a pressure, and a constituent concentration of a gas in a space in which the imprint process is performed.

8. The apparatus according to claim 6, wherein the external environment includes vibration transferred to the imprint apparatus.

9. A method of manufacturing an article, the method comprising:
forming a pattern on a substrate using an imprint apparatus; and
processing the substrate, on which the pattern has been formed, to manufacture the article,
wherein the imprint apparatus performs an imprint process of forming a pattern on an imprint material on the substrate by using a mold and includes:
a detection unit configured to detect an occurrence of an error while the imprint process is performed; and
a control unit configured to perform error processing of ceasing the imprint process and unloading the substrate from the imprint apparatus upon curing the imprint material on the substrate when the detection unit detects the occurrence of the error before the imprint material on the substrate is cured.
